(19) United States
(12) Patent Application Publication
(10) Pub. No.: US 2025/0185256 A1
(43) Pub. Date: Jun. 5, 2025

(54) MAGNETIC MEMORY DEVICE AND METHOD FOR FABRICATING THE SAME

(71) Applicant: UNITED MICROELECTRONICS CORP., Hsinchu (TW)

(72) Inventors: Yan-Jun XU, Singpore (SG); Xiao-Fei HAN, Singapore (SG); Jian-Fei CUI, Singapore (SG)

(21) Appl. No.: 18/389,857

(22) Filed: Dec. 20, 2023

(30) Foreign Application Priority Data
Nov. 30, 2023 (CN) 202311631417.3

(51) Int. Cl. H10B 61/00; G01R 33/09; H10N 50/01; H10N 50/20; H10N 50/85

(52) U.S. Cl. CPC H10B 61/20; G01R 33/098; H10N 50/01; H10N 50/20; H10N 50/85

(57) ABSTRACT

A magnetic memory device includes a substrate, a patterned conductive layer, and a magnetic tunnel junction (MTJ) structure. The substrate includes a memory area and a circuit area. The patterned conductive layer includes a first conductive pattern and a second conductive pattern that are separated from each other. The first conductive pattern is disposed in the memory area, and the second conductive pattern is disposed in the circuit area. The MTJ structure is disposed on the first conductive pattern and electrically contact with the first conductive pattern.

This application claims the benefit of People's Republic of China Application Serial No. 202311631417.3, filed on Nov. 30, 2023, the subject matter of which is incorporated herein by reference.

### BACKGROUND

### Technical Field

The disclosure relates to a memory device and method for fabricating the same, and more particularly to a magnetic memory device and method for fabricating the same.

### Description of Background

With the miniaturization of various electronic apparatuses (such as, wearable devices and automotive chips), and the popularization of the Internet of Things (IOT) and the development of big data (Big Data) analysis technology, the requirements for memory devices with greater storage density and performance built in the control circuits of the electronic apparatuses is significantly increased.

However, currently mature static random access memory (SRAM) devices, dynamic random access memory (DRAM) devices, and flash memory devices are approaching the limits of size miniaturization and efficiency optimization. Therefore, providing a new generation of memory with smaller size, higher storage density, faster reading and writing speed, and energy-saving and non-volatility has become a key issue in this field.

Magnetic memory devices, such as magneto resistive random access memory (MRAM) devices, are regarded as an important type of new generation memory devices because of their advantages of faster reading and writing speed, non-volatility and ease of integration into semiconductor processes. A typical MRAM devices is generally formed on two interconnect metal layers (for example, the second metal (M2) layer and the third metal (M3) layer) by the semiconductor back-end-of-line (BEOL) process, which is difficult to integrate with the manufacturing process of the semiconductor control circuit and requires additional reticles for performing multiple photolithography and etching processes. Accordingly, additional costs must be spent due to embedding MRAM devices into the process for manufacturing the semiconductor control circuit.

Therefore, there is a need of providing an advanced magnetic memory device and method for fabricating the same to obviate the drawbacks encountered from the prior art.

### SUMMARY

One aspect of the present disclosure is to provide a magnetic memory device, wherein the magnetic memory device includes a substrate, a patterned conductive layer, and a magnetic tunnel junction (MTJ) structure. The substrate includes a memory area and a circuit area. The patterned conductive layer includes a first conductive pattern and a second conductive pattern that are separated from each other. The first conductive pattern is disposed in the memory area, and the second conductive pattern is disposed in the circuit area. The MTJ structure is disposed on the first conductive pattern and electrically contact with the first conductive pattern.

Another aspect of the present disclosure is to provide a method for fabricating a magnetic memory device, wherein the method includes steps as follows: Firstly, a substrate including a memory area and a circuit area is provided. Next, a conductive layer is formed on the substrate. Afterwards, a first magnetic layer, an insulating layer and a second magnetic layer are sequentially formed on the conductive layer. Then, the conductive layer, the first magnetic layer, the insulating layer and the second magnetic layer are patterned to form a first conductive pattern and a MTJ structure disposed on the first conductive pattern on the memory region; and to form a second conductive pattern on the circuit area. Wherein the second conductive pattern and the first conductive pattern that separated from each other are included in the patterned conductive layer.

In accordance with the aforementioned embodiments of the present disclosure, a magnetic memory device and method for fabricating the same are provided. The processing steps for forming a spin transfer torque (STT)/spin-orbit torque (SOT) magnetic random access memory unit and that for forming at least one resistance unit are integrated, during the fabrication of semiconductor circuits with magnetic memory devices. Such that, the STT/SOT magnetic random access memory unit and the resistor unit can share the same patterned conductive layer, so as to simplify the manufacturing steps, to save the number of reticles used in the manufacturing process of magnetic memory devices, and to significantly reduce the manufacturing cost of the magnetic memory devices. In one embodiment, the patterned conductive layer may be a SOT metal layer or a STT metal layer.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1A to FIG. 1F are cross-sectional views illustrating a series of processing structures for fabricating a magnetic memory device according to one embodiment of the present disclosure; and

FIG. 2A to FIG. 2F are cross-sectional views illustrating a series of processing structures for fabricating a magnetic memory device according to another embodiment of the present disclosure.

### DETAILED DESCRIPTION

The embodiments as illustrated below provide a magnetic memory device and a method for fabricating the same, which can reduce the manufacturing cost when the magnetic memory device is embedded in a semiconductor circuit. The present disclosure will now be described more specifically with reference to the following embodiments illustrating the structure, method and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

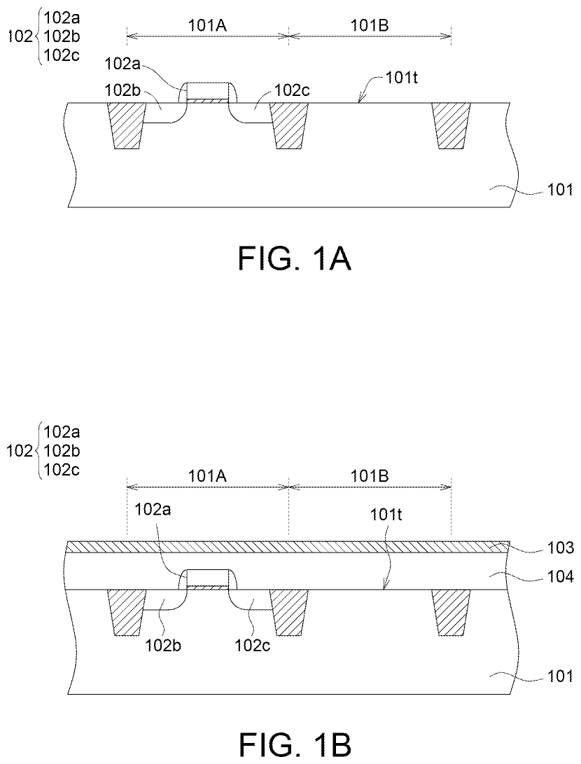

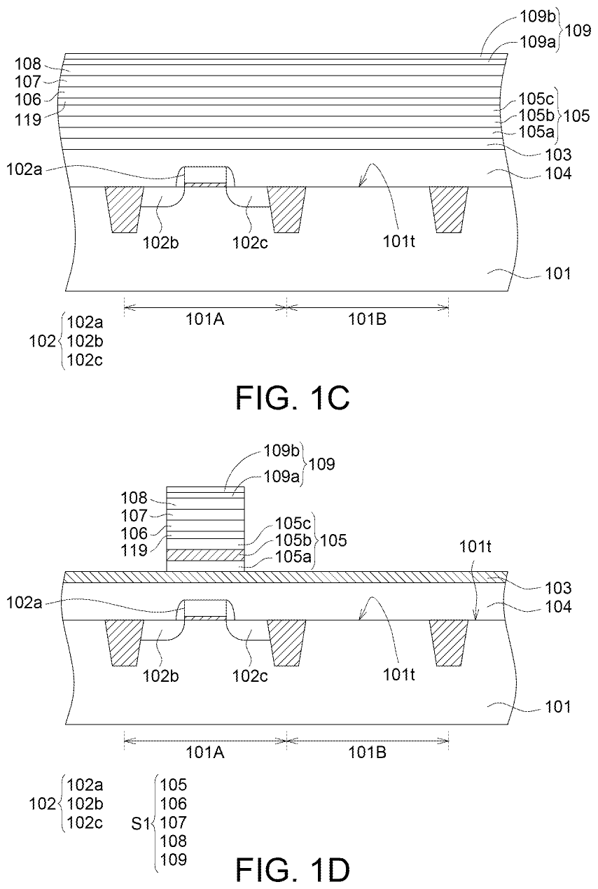

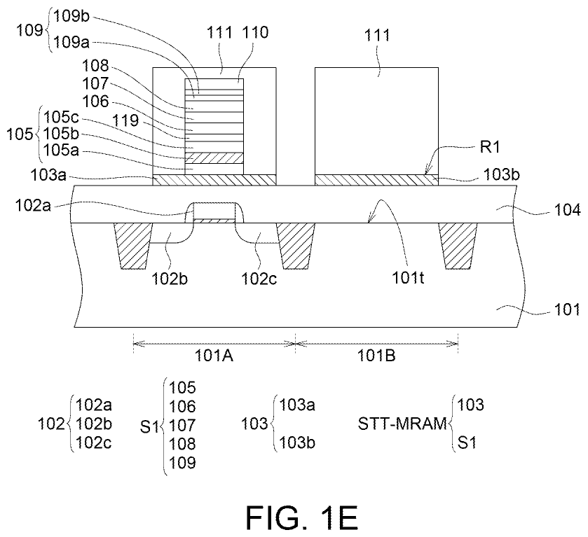

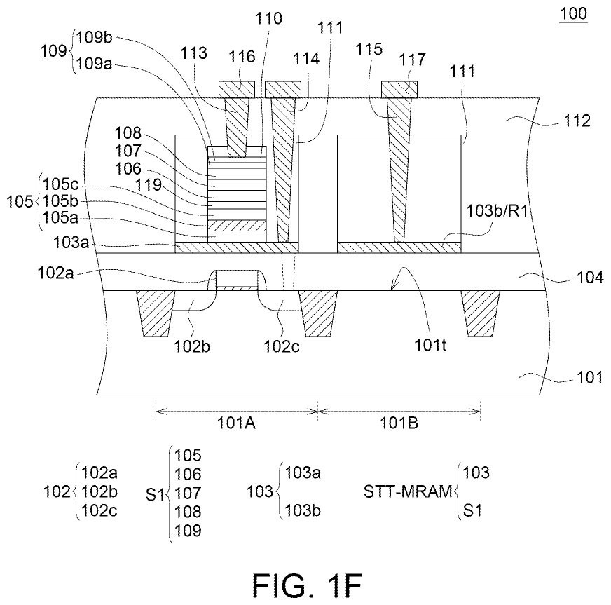

FIG. 1A to FIG. 1F are cross-sectional views illustrating a series of processing structures for fabricating a magnetic memory device 100 according to one embodiment of the present disclosure. The method for fabricating a magnetic memory device 100 includes steps as follows: Firstly, a substrate 101 including a memory area 101A and a circuit area 101B is provided.

In some embodiments of the present disclosure, the substrate 101 can be a silicon-containing substrate, such as a silicon wafer, a silicon-on-insulator (SOI) or any other suitable semiconductor substrate. In the present embodiment, the substrate 101 may be a silicon wafer, and the memory area 101A of the substrate 101 may include (but not limited to) a transistor unit 102, such as a metal-oxide-semiconductor-field effect transistor (MOSFET). As shown in FIG. 1A, the transistor unit 102 includes a gate structure 102a, a source region 102b and a drain region 102c.

Next, a conductive layer 103 is formed on the substrate 101. In some embodiments of the present disclosure, before forming the conductive layer 103, an interlayer dielectric layer (ILD) 104 is formed above the surface 101t of the substrate 101 through a deposition process, such as a chemical vapor deposition (CVD) process, to blanket over the memory area 101A and the circuit area 101B. Then, the conductive layer 103 is formed on the ILD 104 through a deposition process, such as a CVD process (as shown in FIG. 11B). The material constituting the conductive layer 103 may include one of tantalum (Ta), tungsten (W), platinum (Pt), cobalt (Co), ruthenium (Ru), or one of the arbitrary combinations thereof. In the present embodiment, the conductive layer 103 may be a metal layer made of tungsten.

Afterwards, a first magnetic layer 105a, an insulating layer 105b, a second magnetic layer 105c and an upper electrode layer 109 are sequentially formed on the conductive layer 103. In some embodiments of the present disclosure, the material constituting the first magnetic layer 105a and the second magnetic layer 105c may include an iron-containing magnetic material, such as cobalt iron boron (CoFeB). In the present embodiment, a perpendicular magnetic anisotropy (PMA) can be established between the first magnetic layer 105a and the second magnetic layer 105c.

The material constituting the insulating layer 105b may include magnesium oxide (MgO), amorphous aluminum oxide (AlOx) or amorphous hafnium oxide (HfOₓ). The conductive material constituting the upper electrode layer 109 may include (but not limited to) Ru, Ta, Pt, copper (Cu), gold (Au), aluminum (AI) or any one of the arbitrary combinations thereof. In the present embodiment, the material constituting the insulating layer 105b preferably includes MgO. The upper electrode layer 109 may be a stacked structure composed of a Ta metal layer 109a and a Ru metal layer 109b.

In one embodiment of the present disclosure, after the second magnetic layer 105c is formed, a synthetic antiferromagnetic (SAF) structure can be optionally formed above the second magnetic layer 105c, and the upper electrode layer 109 is then formed thereon. For example, a bottom SAF layer 106 can be formed between the second magnetic layer 105c and the upper electrode layer 109. In one embodiment, the bottom SAF layer 106 can be a periodic multi-layer structure formed by n cobalt/nickel (Co/Ni) alternately stacking layers, wherein n is an integer greater than or equal to 1 (n>1).

In the present embodiment, another (upper) SAF layer 108 can be optionally formed above the bottom SAF layer 106 and connected to the bottom SAF layer 106 through the coupling layer 107, whereby the bottom SAF layer 106, the coupling layer 107 and the upper SAF layer 108 can be combined to form the SAF structure. As shown in FIG. 1C, the bottom SAF layer 106, the coupling layer 107 and the upper SAF layer 108 can be formed between the second magnetic layer 105c and the upper electrode layer 109. The coupling layer 107 may include Ru. The structure and materials of the upper SAF layer 108 may be the same as or different from the bottom SAF layer 106. The upper SAF layer 108 may be a periodic multi-layer stack structure formed by m (for example, m is an integer greater than or equal to 1 (m≥1)) cobalt/platinum (Co/Pt) alternately stacking layers. Before forming the bottom SAF layer 106, a bridge layer 119, such as an W metal layer with a thickness of approximately 0.3 nanometers (nm), may preferably be formed above the second magnetic layer 105c.

Then, the upper electrode layer 109, the upper SAF layer 108, the coupling layer 107, the bottom SAF layer 106, the second magnetic layer 105c, the insulating layer 105b and the first magnetic layer 105a are etched using a patterned hard mask layer 110 (for example, made of silicon nitride) as an etching mask, and using the conductive layer 103 as the etching stop layer. Thereby, the remaining portions of the upper electrode layer 109, the upper SAF layer 108, the coupling layer 107, the bottom SAF layer 106, the second magnetic layer 105c, the insulating layer 105b and the first magnetic layer 105a disposed on the memory region 101A can be combined to form a stacked structure S1; and the portion of the conductive layer 103 disposed on the circuit area 101B can be exposed (at this time, the conductive layer 103 covers both the circuit area 101B and the memory area 101A).

As shown in FIG. 1D, the portions of the second magnetic layer 105c, the insulating layer 105b and the first magnetic layer 105a remaining on the memory area 101A can be combined to form a vertical MTJ structure 105. The first magnetic layer 105a includes ferromagnetic material that is not fixed or pinned in a specific magnetic orientation; and the magnetic orientation of the ferromagnetic material of the first magnetic layer 105a can be rotated during the subsequent write process of the spin transfer torque magnetic random access memory (STT-MRAM). The second magnetic layer 105c can serve as a free layer of the vertical MTJ structure 105, wherein the magnetic orientation of the second magnetic layer 105c can be controlled by the bottom SAF layer 106, the coupling layer 107 and the upper SAF layer 108 to make the magnetic orientation of the first magnetic layer 105a parallel or anti-parallel to that of the second magnetic layer 105c. For example, when the magnetic orientation of the first magnetic layer 105a is parallel to that of the second magnetic layer 105c, the vertical resistance parallel to the vertical MTJ is very small and is generally regarded as a stored value=0; and when the magnetic orientation of the first magnetic layer 105a is anti-parallel to that of the second magnetic layer 105c, the vertical resistance anti-parallel to the vertical MTJ is very large and is generally regarded as a stored value=1.

The insulating layer 105b can serve as a tunneling barrier that blocks electrons from traveling freely in the vertical MTJ structure 105. It should be noted that although the bottom SAF layer 106, the coupling layer 107 and the upper SAF layer 108 can be used to fix the magnetic orientation of the second magnetic layer 105c, but the mechanism for fixing the magnetic orientations is quite complex. For example, in the SAF structure, whether the magnetic orientation of the bottom SAF layer 106 is parallel or anti-parallel to that of the upper SAF layer 108 may depend on the thickness of the coupling layer 107; and whether the magnetic orientation the bottom SAF layer 106 is parallel or anti-parallel to that of the second magnetic layer 105c may depend on the thickness of the bridge layer 119 between the second magnetic layer 105c and the bottom SAF layer 106.

Thereinafter, an insulating covering layer 111 is formed on the memory area 101A and the circuit area 101B, covering the stacked structure S1 and the exposed portion of the conductive layer 103. The insulating covering layer 111 and the conductive layer 103 are then etched to remove a portion of the insulating covering layer 111 and the portion of the conductive layer 103 both disposed on the memory area 101A. Thereby a first conductive pattern 103a is formed in the memory area 101A, and a second conductive pattern 103b is formed in the circuit area 101B. Wherein, the first conductive pattern 103a and the second conductive pattern 103b are both included in the patterned conductive layer 103 and are separated from each other.

In the present embodiment, as shown in FIG. 1E, the stacked structure S1 is disposed on the first conductive pattern 103a, and the bottom size of the stacked structure S1 is substantially smaller than the area of the first conductive pattern 103a, so that a portion of the first conductive pattern 103a is not overlapped with the stacked structure S1. The vertical MTJ structure 105 and the first conductive pattern 103a disposed below it, as well as the remaining portions of the upper electrode layer 109, the upper SAF layer 108, the coupling layer 107, and the bottom SAF layer 106 stacked above it can be combined to form a STT-MRAM unit. The remaining portion of the second conductive pattern 103b disposed on the circuit area 101B can form a resistance unit R1. In some embodiments, the portion of the first conductive pattern 103a that is not covered by the stacked structure S1 may be completely removed.

Subsequently, a series of BEOL processes are performed. For example, a metal damascene process is performed to form an ILD 112 covering the memory area 101A and the circuit area 101B and a metal interconnection structure (including via plugs 113, 114 and 115 respectively) passing through the ILDs 104 and 112 and/or the insulating covering layer 111. Thereby the upper electrode layer 109 of the STT-MRAM unit can be electrically connected to a bit line 116 through the via plug 113; the STT-MRAM unit can be electrically connected to the transistor unit 102 through the via plug 114. (For example, the first conductive pattern 103a of the STT-MRAM unit can be electrically connected to the drain region 102c of the transistor unit 102 through the via plug 114); and one end of the second conductive pattern 103b of the resistor unit R1 can be electrically connected to an external circuit 117 through the via plug 115 (the other end of the second conductive pattern 103b is electrically connected to another electrode (not shown) through other wires), so as to form the magnetic memory 100 shown in FIG. 1F.

The processing steps for manufacturing the vertical MTJ structure 105 of the STT-MRAM unit and that for manufacturing at least one resistance unit R1 in the magnetic memory device 100 can be integrated, such that the STT-MRAM unit and the resistor unit R1 can share the same patterned conductive layer 103, the process for manufacturing the magnetic memory device 100 can be simplified, the number of reticles used in the manufacturing process can be saved, and the manufacturing cost of the magnetic memory device 100 can be significantly reduced.

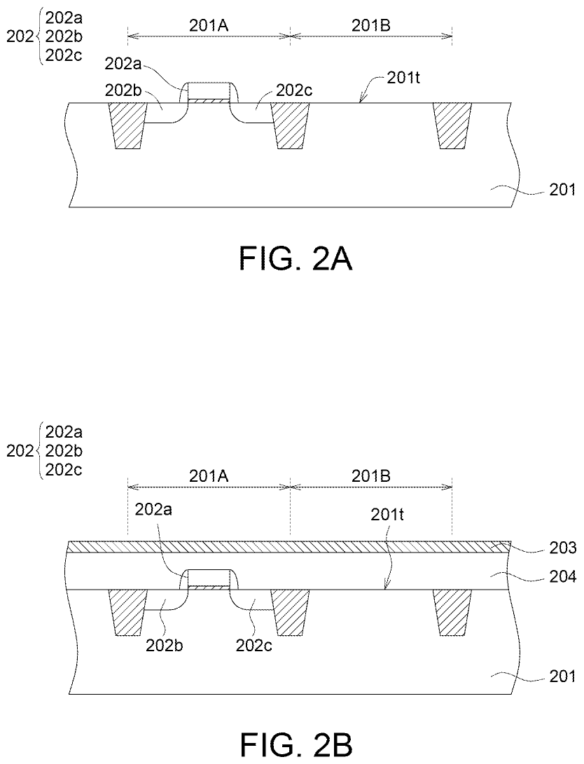

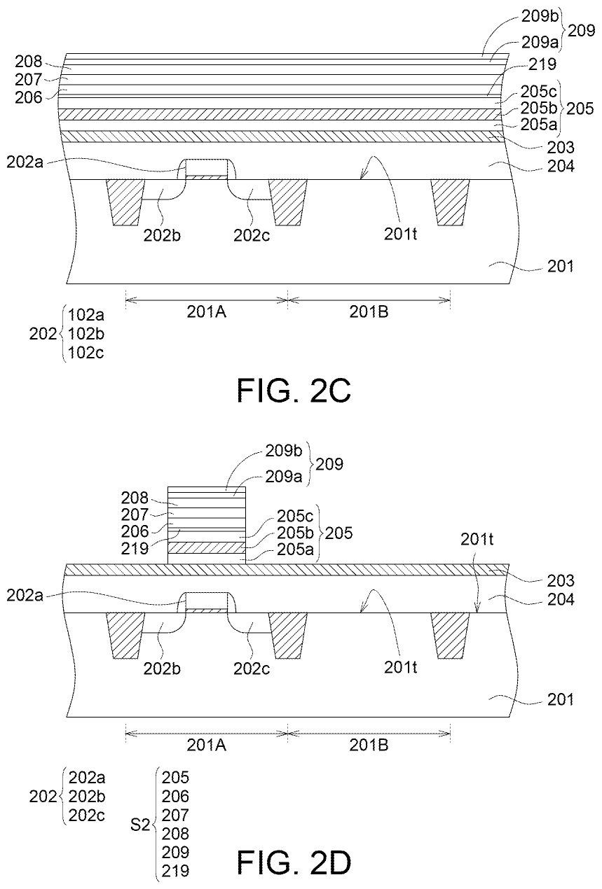

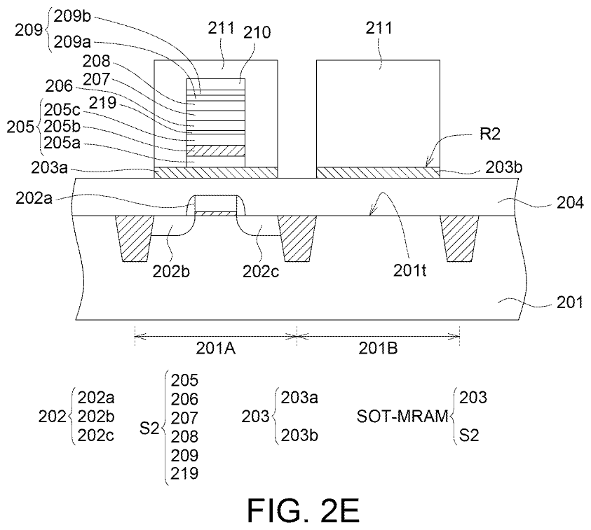

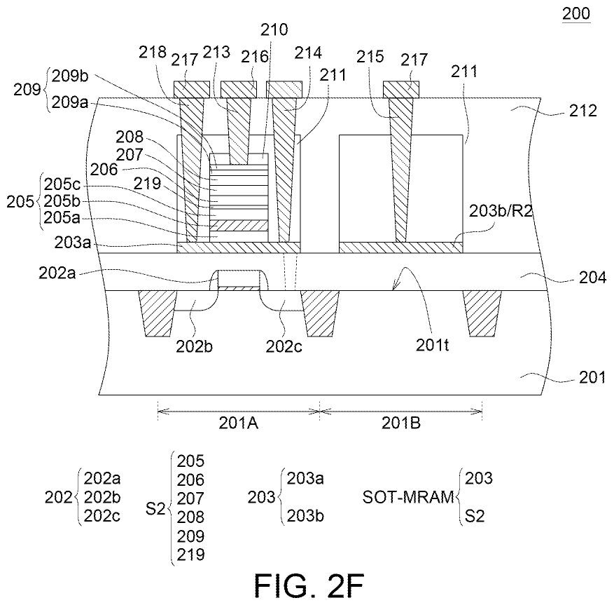

FIG. 2A to FIG. 2F are cross-sectional views illustrating a series of processing structures for fabricating a magnetic memory device 200 according to another embodiment of the present disclosure. The method for fabricating a magnetic memory device 200 includes steps as follows: Firstly, a substrate 201 including a memory area 201A and a circuit area 201B is provided. In the present embodiment, the substrate 201 may be a silicon wafer, and the memory area 201A of the substrate 201 may include (but not limited to) a transistor unit 202, such as a MOSFET. As shown in FIG. 2A, the transistor unit 202 includes a gate structure 202a, a source region 202b and a drain region 202c.

Next, a conductive layer 203 is formed on the substrate 201. In some embodiments of the present disclosure, before forming the conductive layer 203, an ILD 204 is formed above the surface 201t of the substrate 201 through a deposition process, such as a CVD process, to blanket over the memory area 201A and the circuit area 201B. Then, the conductive layer 203 is formed on the ILD 204 through a deposition process, such as a CVD process (as shown in FIG. 2B).

The conductive layer 203 can be a spin Hall metal layer that can generate a spin orbit torque (SOT) greater than 0.5 (hereinafter referred to as a SOT metal layer). The material constituting the conductive layer 203 includes (but not limited to) one of Ta, W, Pt, or any one of the arbitrary combinations thereof. In the present embodiment, the conductive layer 203 may be a Pt metal layer.

Afterwards, a first magnetic layer 205a, an insulating layer 205b, a second magnetic layer 205c and an upper electrode layer 209 are sequentially formed on the conductive layer 203. In some embodiments of the present disclosure, the material constituting the first magnetic layer 205a and the second magnetic layer 205c may include an iron-containing magnetic material, such as cobalt iron boron (CoFeB). In the present embodiment, there an in-plane magnetic anisotropy (IMA) can be established between the first magnetic layer 205a and the second magnetic layer 205c. The material constituting the insulating layer 205b may include magnesium oxide (MgO). The upper electrode layer 209 may be a stacked structure composed of a Ta metal layer 209a and a Ru metal layer 209b.

In one embodiment of the present disclosure, after the second magnetic layer 205c is formed, two SAF layers (such as an upper SAF layers 208 and a bottom SAF layer 206) with the same or different structures and materials may also be optionally formed on the second magnetic layer 205c. The bottom SAF layer 206, the upper SAF layers 208 and a ruthenium coupling layer 207 connecting these two are combined to form a SAF structure. After that, the upper electrode layer 209 is formed thereon, so as to make the upper SAF layer 208 and the bottom SAF layer 206 between the second magnetic layer 205c and the upper electrode layer 209. In the present embodiment, the upper SAF layer 208 and the bottom SAF layer 206 are both a periodic multilayer structure formed by n cobalt/nickel (Co/Ni) alternately stacking layers, and are connected to each other through the Ru coupling layer 207. Wherein, n is an integer greater than or equal to 1 (n≥1). Before forming the bottom SAF layer 206, a bridge layer 219, such as an W metal layer with a thickness of approximately 0.3 nm, may preferably be formed above the second magnetic layer 205c.

Then, the upper electrode layer 209, the upper SAF layer 208, the Ru coupling layer 207, the bridge layer 219, the bottom SAF layer 206, the second magnetic layer 205c, the insulating layer 205b and the first magnetic layer 205a are etched, in which a patterned hard mask layer 210 (e.g., a silicon nitride layer) is used as an etching mask, and the conductive layer 203 is used as an etching stop layer. Thereby, the remaining portions of the upper electrode layer 209, the upper SAF layer 208, the Ru coupling layer 207, the bridge layer 219, the bottom SAF layer 206, the second magnetic layer 205c, the insulating layer 205b and the first magnetic layer 205a disposed on the memory region 201A can be combined to form a stacked structure S2; and the portion of the conductive layer 203 disposed on the circuit area 201B can be exposed (at this time, the conductive layer 203 covers both the circuit area 201B and the memory area 201A).

Wherein, portions of the second magnetic layer 205c, the insulating layer 205b and the first magnetic layer 205a remaining on the memory area 201A are combined to form a MTJ structure with an IMA (as shown in FIG. 2D). The first magnetic layer 205a can be used as a free layer of the MTJ structure; the insulating layer 205b can be used as a tunneling barrier layer in the MTJ structure; the magnetic orientation of the second magnetic layer 205c can be fixed by the bottom SAF layer 206, the Ru coupling layer 207 and the upper SAF layer 208 and can be used as a reference layer of the MTJ structure for referencing the magnetic intensity thereof.

Thereinafter, an insulating covering layer 211 is formed on the memory area 201A and the circuit area 201B, covering the stacked structure S2 and the exposed portion of the conductive layer 203. The insulating covering layer 211 and the conductive layer 203 are then etched to remove a portion of the insulating covering layer 211 and the portion of the conductive layer 203 both disposed on the memory area 201A. Thereby a first conductive pattern 203a is formed in the memory area 201A, and a second conductive pattern 203b is formed in the circuit area 201B. Wherein, the first conductive pattern 203a and the second conductive pattern 203b are both included in the patterned conductive layer 203 and are separated from each other.

In the present embodiment, as shown in FIG. 2E, the stacked structure S2 is disposed on the first conductive pattern 203a, and the bottom size of the stacked structure S2 is substantially smaller than the area of the first conductive pattern 203a, so that a portion of the first conductive pattern 203a is not overlapped with the stacked structure S2. The vertical MTJ structure 205 and the first conductive pattern 203a disposed below it, as well as the remaining portions of the upper electrode layer 209, the upper SAF layer 208, the coupling layer 207, and the bottom SAF layer 206 stacked above it can be combined to form a spin-orbit torque magnetic random access memory (SOT-MRAM) unit. The remaining portion of the second conductive pattern 203b disposed on the circuit area 201B can form a resistance unit R2.

Subsequently, a series of BEOL processes are performed. For example, a metal damascene process is performed to form an ILD 212 covering the memory area 201A and the circuit area 201B and a metal interconnection structure (including via plugs 213, 214, 215 and 218 respectively) passing through the ILDs 204 and 212 and/or the insulating covering layer 211. Thereby the upper electrode layer 209 of the SOT-MRAM unit can be electrically connected to a bit line 216 through the via plug 213; the SOT-MRAM unit can be electrically connected to the transistor unit 202 through the via plug 214 or 218. (For example, two ends of the first conductive pattern 203a respectively disposed on the left and right sides of the MTJ structure are electrically connected to the drain region 202c of the transistor unit 202 and the writing line/word line through the via plugs 214 and 218); and one end of the second conductive pattern 203b of the resistor unit R2 can be electrically connected to an external circuit 217 through the via plug 215 (the other end of the second conductive pattern 203b is electrically connected to another electrode (not shown) through other wires), so as to form the magnetic memory 200 shown in FIG. 2F.

The processing steps for manufacturing the MTJ structure 205 of the SOT-MRAM unit and that for manufacturing at least one resistance unit R2 in the magnetic memory device 200 can be integrated, such that the SOT-MRAM unit and the resistor unit R2 can share the same patterned conductive layer 203, the process for manufacturing the magnetic memory device 200 can be simplified, the number of reticles used in the manufacturing process can be saved, and the manufacturing cost of the magnetic memory device 200 can be significantly reduced.

In accordance with the aforementioned embodiments of the present disclosure, a magnetic memory device and method for fabricating the same are provided. The processing steps for forming a SOT-MRAM/STT-MRAM unit and that for forming at least one resistance unit are integrated, during the fabrication of semiconductor circuits with magnetic memory devices. Such that, the SOT-MRAM/STT-MRAM unit and the resistor unit can share the same patterned conductive layer, so as to simplify the manufacturing steps, to save the number of reticles used in the manufacturing process of magnetic memory devices, and to significantly reduce the manufacturing cost of the magnetic memory devices. In one embodiment, the patterned conductive layer may be a SOT metal layer or a STT metal layer.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A magnetic memory device, comprising:
a substrate comprising a memory area and a circuit area;
a patterned conductive layer comprising a first conductive pattern and a second conductive pattern that are separated from each other, wherein the first conductive pattern is disposed in the memory area, and the second conductive pattern is disposed in the circuit area; and
a magnetic tunnel junction (MTJ) structure disposed on the first conductive pattern and electrically contact with the first conductive pattern.

2. The magnetic memory device according to claim 1, further comprising:
a dielectric layer, covering the patterned conductive layer;
at least one first via plug, passing through the dielectric layer and electrically contacting with the first conductive pattern; and
a second via plug, passing through the dielectric layer and electrically contacting with the second conductive pattern.

3. The magnetic memory device according to claim 2, wherein the MTJ structure is a spin transfer torque (STT) structure.

4. The magnetic memory device according to claim 3, wherein the at least one first via plug is a metal plug.

5. The magnetic memory device according to claim 3, wherein the patterned conductive layer comprises tungsten (W).

6. The magnetic memory device according to claim 2, wherein the MTJ structure is a spin orbit torque (SOT) structure.

7. The magnetic memory device according to claim 6, wherein the at least one first via plug comprises two metal plugs.

8. The magnetic memory device according to claim 6, wherein the patterned conductive layer comprises one of tantalum (Ta), W, platinum (Pt), cobalt (Co), ruthenium (Ru), or one of arbitrary combinations thereof.

9. The magnetic memory device according to claim 6, wherein the SOT structure comprises a magnetic layer/non-magnetic layer/magnetic layer stack structure.

10. The magnetic memory device according to claim 9, wherein the magnetic layer/non-magnetic layer/magnetic layer stack structure comprises a cobalt iron boron (CoFeB)/magnesium oxide (MgO)/cobalt iron boron (CoFeB) stack structure.

11. Method for fabricating a magnetic memory device, comprising:
providing a substrate that comprises a memory area and a circuit area,
forming a conductive layer on the substrate;
sequentially forming a first magnetic layer, an insulating layer and a second magnetic layer on the conductive layer; and
patterning the conductive layer, the first magnetic layer, the insulating layer and the second magnetic layer to form a first conductive pattern and a MTJ structure disposed on the first conductive pattern on the memory region; and to form a second conductive pattern on the circuit area;
wherein the second conductive pattern and the first conductive pattern that separated from each other are included in the patterned conductive layer.

12. The method according to claim 11, further comprising:
forming a dielectric layer, covering the patterned conductive layer;
forming at least one first via plug, passing through the dielectric layer and electrically contacting with the first conductive pattern; and
forming a second via plug, passing through the dielectric layer and electrically contacting with the second conductive pattern.

13. The method according to claim 12, wherein the MTJ structure is a STT structure.

14. The method according to claim 13, wherein the at least one first via plug is a metal plug.

15. The method according to claim 13, wherein the patterned conductive layer comprises W.

16. The method according to claim 12, wherein the MTJ structure is a SOT structure.

17. The method according to claim 16, wherein the at least one first via plug comprises two metal plugs.

18. The method according to claim 16, wherein the patterned conductive layer comprises one of Ta, W, Pt, Co, Ru, or one of arbitrary combinations thereof.

19. The method according to claim 16, wherein the SOT structure comprises a magnetic layer/non-magnetic layer/magnetic layer stack structure.

20. The magnetic memory device according to claim 19, wherein the magnetic layer/non-magnetic layer/magnetic layer stack structure comprises a CoFeB/MgO/CoFeB stack structure.
